(19) United States
(12) Patent Application Publication
(10) Pub. No.: US 2025/0089251 A1
(43) Pub. Date: Mar. 13, 2025

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Masaki TSUJI, Yokkaichi Mie (JP)

(73) Assignee: Kioxia Corporation, Tokyo (JP)

(21) Appl. No.: 18/819,190

(22) Filed: Aug. 29, 2024

(30) Foreign Application Priority Data
Sep. 8, 2023 (JP) 2023-145759

(51) Int. Cl. H10B 43/27

(52) U.S. Cl. CPC H10B 43/27

(57) ABSTRACT

According to one embodiment, a semiconductor memory device includes: a first semiconductor layer; a second semiconductor layer provided above the first semiconductor layer; a third semiconductor layer interposed between the first and second semiconductor layers; a stacked body provided above the second semiconductor layer, in which a plurality of conductive layers are stacked one by one while being separated from each other; and a pillar including a channel layer that extends through the stacked body, the second semiconductor layer, and the third semiconductor layer in a stacking direction of the stacked body and reaches a predetermined depth of the first semiconductor layer. The channel layer is electrically connected to the third semiconductor layer on a side surface. The pillar has a cross-sectional area as viewed from the stacking direction that is larger at a height position of the first semiconductor layer than at a height position of the third semiconductor layer, and has a stepped portion at a height position of an interface between the first semiconductor layer and the third semiconductor layer.

### CROSS-REFERENCE TO RELATED APPLICATIONS

This application is based upon and claims the benefit of priority from Japanese Patent Application No. 2023-145759, filed on Sep. 8, 2023; the entire contents of which are incorporated herein by reference.

### FIELD

Embodiments described herein relate generally to a semiconductor memory device and a method of manufacturing a semiconductor memory device.

### BACKGROUND

In a semiconductor memory device such as a three-dimensional nonvolatile memory, a plurality of pillars penetrating a stacked body in which a plurality of conductive layers are stacked and reaching a predetermined depth of a source line below the stacked body are formed. Since the portion of the pillars penetrating the stacked body and the portion of the pillars in the source line are formed in different steps, for example, positional deviation may occur between these portions, and the channel layer of the pillars may be discontinuously formed.

### BRIEF DESCRIPTION OF THE DRAWINGS

FIG. 1 is a cross-sectional view along an X direction illustrating an example of a schematic configuration of a semiconductor memory device according to an embodiment;

FIGS. 2A to 2D are cross-sectional views illustrating an example of a configuration of the semiconductor memory device according to the embodiment;

FIGS. 3A to 3D are cross-sectional views along a Y direction sequentially illustrating parts of the procedure of a method of manufacturing the semiconductor memory device according to the embodiment;

FIGS. 4A to 4C are cross-sectional views along the Y direction sequentially illustrating parts of the procedure of a method of manufacturing the semiconductor memory device according to the embodiment;

FIGS. 5A to 5C are cross-sectional views along the Y direction sequentially illustrating parts of the procedure of a method of manufacturing the semiconductor memory device according to the embodiment;

FIGS. 6A to 6C are cross-sectional views along the Y direction sequentially illustrating parts of the procedure of a method of manufacturing the semiconductor memory device according to the embodiment;

FIGS. 7A to 7C are cross-sectional views along the Y direction sequentially illustrating parts of the procedure of a method of manufacturing the semiconductor memory device according to the embodiment;

FIGS. 8A to 8C are cross-sectional views along the Y direction sequentially illustrating parts of the procedure of a method of manufacturing the semiconductor memory device according to the embodiment;

FIGS. 9A to 9C are cross-sectional views along the Y direction sequentially illustrating parts of the procedure of a method of manufacturing the semiconductor memory device according to the embodiment;

FIGS. 10A to 10D are cross-sectional views along the Y direction sequentially illustrating parts of the procedure of a method of manufacturing the semiconductor memory device according to a comparative example;

FIGS. 11A and 11B are cross-sectional views along the Y direction sequentially illustrating parts of the procedure of a method of manufacturing the semiconductor memory device according to the comparative example;

FIGS. 12A and 12B are schematic diagrams illustrating examples of pillars in which a positional deviation occurs in memory hole portions of the semiconductor memory devices according to the embodiment and the comparative example;

FIG. 13 is a cross-sectional view along the Y direction illustrating an example of a configuration of a semiconductor memory device according to a modification of the embodiment;

FIGS. 14A to 14E are cross-sectional views along the Y direction sequentially illustrating parts of the procedure of the method of manufacturing the semiconductor memory device according to the modification of the embodiment; and

FIGS. 15A to 15C are cross-sectional views along the Y direction sequentially illustrating parts of the procedure of the method of manufacturing the semiconductor memory device according to the modification of the embodiment.

### DETAILED DESCRIPTION

According to one embodiment, a semiconductor memory device includes: a first semiconductor layer; a second semiconductor layer provided above the first semiconductor layer; a third semiconductor layer interposed between the first and second semiconductor layers; a stacked body provided above the second semiconductor layer, in which a plurality of conductive layers are stacked one by one while being separated from each other; and a pillar including a channel layer that extends through the stacked body, the second semiconductor layer, and the third semiconductor layer in a stacking direction of the stacked body and reaches a predetermined depth of the first semiconductor layer. The channel layer is electrically connected to the third semiconductor layer on a side surface. The pillar has a cross-sectional area as viewed from the stacking direction that is larger at a height position of the first semiconductor layer than at a height position of the third semiconductor layer, and has a stepped portion at a height position of an interface between the first semiconductor layer and the third semiconductor layer.

Embodiments of the present invention will be explained in detail with reference to the drawings. Note that the present invention is not limited to the following embodiments. In addition, constituent elements in the following embodiments include those that can be easily assumed by those skilled in the art or those that are substantially the same.

### (Configuration Example of Semiconductor Memory Device)

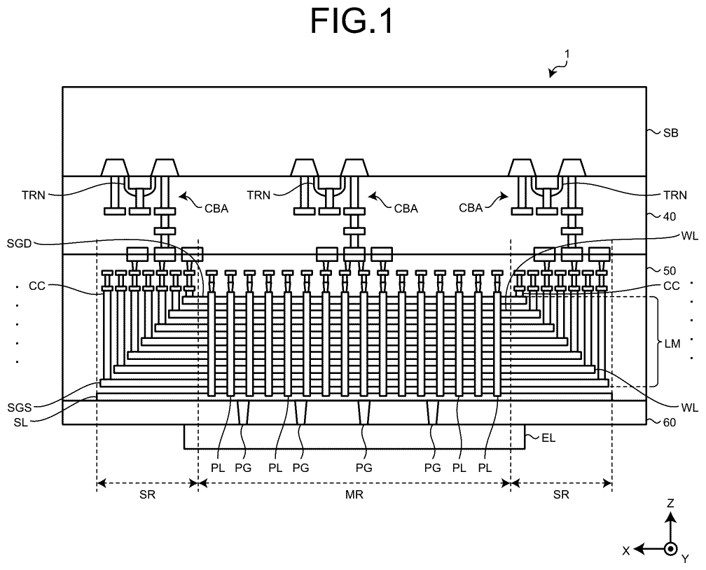

FIG. 1 is a cross-sectional view along an X direction illustrating an example of a schematic configuration of a semiconductor memory device 1 according to an embodiment. Note, however, that in FIG. 1, hatching is omitted in consideration of visibility of the drawing.

Note that in the present specification, both the X direction and a Y direction are directions along the orientation of a surface of a word line WL to be described later, and the X direction and the Y direction are orthogonal to each other. Furthermore, in the present specification, a Z direction is a direction along the stacking direction of a stacked body LM to be described later, and is a direction orthogonal to the X direction and the Y direction.

In addition, in the present specification, a side on which a source line SL to be described later is arranged with respect to the stacked body LM is defined as a lower direction in the semiconductor memory device 1.

As illustrated in FIG. 1, the semiconductor memory device 1 includes a semiconductor substrate SB on which an electrode film EL, the source line SL, the stacked body LM, and a peripheral circuit CBA are provided in order from the lower side of the drawing.

The source line SL is disposed on the electrode film EL via an insulating layer 60. A plurality of plugs PG are disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. The stacked body LM in which a plurality of word lines WL are stacked is disposed on the source line SL.

The stacked body LM has a structure in which one or more selection gate lines SGS, a plurality of word lines WL, and one or more selection gate lines SGD are stacked in order from the lower side of the drawing. A memory region MR is arranged at a central portion along the direction in which each layer of the stacked body LM extends, and stepped regions SR are arranged at both ends of the stacked body LM.

In the memory region MR, a plurality of pillars PL penetrating the stacked body LM in the stacking direction are arranged. The lower end of the pillar PL reaches the source line SL. A plurality of memory cells are formed at intersections of the pillars PL and the word lines WL. As a result, the semiconductor memory device 1 is configured as, for example, a three-dimensional nonvolatile memory in which memory cells are three-dimensionally arranged in the memory region MR.

In the stepped region SR, the plurality of word lines WL and selection gate lines SGD and SGS are processed in a stepped shape and are terminated. At this time, as the distance from the memory region MR increases, the plurality of word lines WL and the like forming the terrace portion move from the upper layer side to the lower layer side, so that the height position of the terrace portion lowers toward the source line SL side.

A contact CC connected to the word line WL or the like of each layer is disposed in the terrace portion of each stage formed by the plurality of word lines WL or the like. The word lines WL and the like stacked in multiple layers are individually drawn out by these contacts CC.

More specifically, a write voltage, a read voltage, and the like are applied from these contacts CC to memory cells included in the memory region MR in the central portion of the stacked body LM via the word lines WL corresponding to the memory cells.

The stacked body LM, the pillars PL, and the contacts CC are covered with an insulating layer 50. The insulating layer 50 also extends to the periphery of these configurations.

The semiconductor substrate SB above the insulating layer 50 is, for example, a silicon substrate or the like. The peripheral circuit CBA including a transistor TRN, wiring, and the like is disposed on the surface of the semiconductor substrate SB. Various voltages applied from the contacts CC to the memory cells are controlled by the peripheral circuits CBA electrically connected to the contacts CC. As a result, the peripheral circuit CBA controls the electrical operation of the memory cell.

The peripheral circuit CBA is covered with an insulating layer 40, and the insulating layer 40 and the insulating layer 50 covering the plurality of word lines WL and the like are joined to form the semiconductor memory device 1 including the configurations of the stacked body LM, the pillars PL, the contacts CC, and the like, and the peripheral circuit CBA.

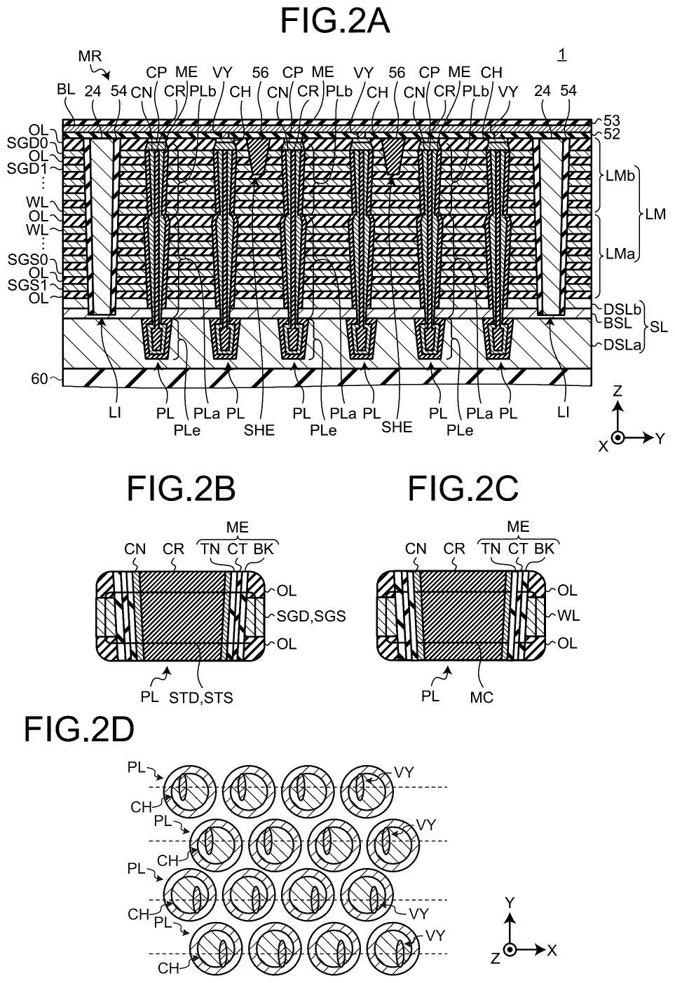

Next, a detailed configuration example of the semiconductor memory device 1 will be described with reference to FIGS. 2A to 2D. FIGS. 2A to 2D are cross-sectional views illustrating an example of a configuration of the semiconductor memory device 1 according to the embodiment.

More specifically, FIG. 2A is a cross-sectional view along the Y direction in the memory region MR of the semiconductor memory device 1. In FIG. 2A, structures below the insulating layer 60 and above an insulating layer 53 described later are omitted.

FIG. 2B is an enlarged cross-sectional view of the pillar PL at the height position of the arbitrary selection gate lines SGD and SGS. FIG. 2C is an enlarged cross-sectional view of the pillar PL at a height position of an arbitrary word line WL.

FIG. 2D is a partially enlarged top view of the memory region MR. Note, however, that in FIG. 2D, some configurations of the insulating layers 52 and 53 and the like are omitted.

As illustrated in FIG. 2A, the source line SL has a multilayer structure in which, for example, a lower source line DSLa as a first semiconductor layer, an intermediate source line BSL as a third semiconductor layer, and an upper source line DSLb as a second semiconductor layer are stacked in this order on the insulating layer 60.

The lower source line DSLa, the intermediate source line BSL, and the upper source line DSLb are, for example, polysilicon layers. Among these layers, at least the intermediate source line BSL is a conductive polysilicon layer in which an n-type impurity such as phosphorus is diffused.

Note that the source line SL is connected to the peripheral circuit CBA via the electrode film EL by a through contact (not illustrated) extending from the electrode film EL to the peripheral circuit CBA in the insulating layer 50 outside the stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. One or more selection gate lines SGS are arranged below the lowermost word line WL of the stacked body LMa. In the example of FIG. 2A, the stacked body LMa includes two selection gate lines SGS0 and SGS1 in order from the upper layer side.

The stacked body LMb is disposed on the stacked body LMa. One or more selection gate lines SGD are arranged above the uppermost word line WL of the stacked body LMb. In the example of FIG. 2A, the stacked body LMb includes two selection gate lines SGD0 and SGD1 in order from the upper layer side.

Note, however, that the number of these word lines WL and selection gate lines SGD and SGS stacked in the stacked body LM is arbitrary. The word lines WL and the selection gate lines SGD and SGS as the plurality of conductive layers are, for example, tungsten layers or molybdenum layers. The plurality of insulating layers OL disposed between the conductive layers are, for example, silicon oxide layers or the like.

An upper surface of the stacked body LM is covered with the insulating layer 52. The insulating layer 52 is covered with the insulating layer 53. Each of the insulating layers 52 and 53 forms a part of the insulating layer 50 in FIG. 1.

The stacked body LM is divided in the Y direction by a plurality of plate contacts LI. That is, the plate contacts LI are arranged in the Y direction and extend in the stacking direction of the stacked body LM and a direction along the X direction.

As described above, the plate contact LI continuously extends in the stacked body LM from one end portion to the other end portion of the stacked body LM in the X direction. Moreover, the plate contact LI penetrates the stacked body LM and the upper source line DSLb and reaches the intermediate source line BSL.

Each of the plate contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers side walls of the plate contact LI facing each other in the Y direction. The conductive layer 24 is filled inside the insulating layer 54, and electrically connected to source line SL including the intermediate source line BSL. Note, however, that instead of the plate contact LI, a plate-like member filled with an insulating layer may penetrate the stacked body LM and extend in the direction along the X direction, thereby dividing the stacked body LM in the Y direction.

Between the plate contacts LI adjacent in the Y direction, a plurality of separation layers SHE penetrating the selection gate line SGD and extending in the direction along the X direction are arranged. The separation layer SHE includes an insulating layer 56 such as a silicon oxide layer, for example, and separates the selection gate line SGD into a plurality of sections. In other words, the separation layer SHE penetrates the upper layer portion of the stacked body LM and extends in the direction along the X direction, so that the upper layer portion of the stacked body LM is partitioned into patterns of the plurality of selection gate lines SGD.

In the memory region MR, a plurality of pillars PL penetrating the stacked body LM, the upper source line DSLb, and the intermediate source line BSL and reaching a predetermined depth in the lower source line DSLa are dispersedly arranged.

The plurality of pillars PL take, for example, a staggered arrangement when viewed from the stacking direction of the stacked body LM. Each pillar PL has, for example, a circular shape, an elliptical shape, an oval shape, or the like as a cross-sectional shape in a direction along the direction of the layers of the stacked body LM, that is, in a direction along an XY plane.

Moreover, the pillar PL includes a lower end PLe located in the lower source line DSLa, a portion PLa penetrating the stacked body LMa, the upper source line DSLb, and the intermediate source line BSL, and a portion PLb penetrating the stacked body LMb.

The portion PLa penetrating the stacked body LMa and other parts and the portion PLb penetrating the stacked body LMb each have a tapered shape in which the diameter and the cross-sectional area decrease from an upper end toward a lower end. Alternatively, these portions PLa and PLb each have a bowing shape having the largest diameter and cross-sectional area at a predetermined position between the upper end and the lower end, for example.

The lower end PLe in the lower source line DSLa has, for example, a tapered shape in which the diameter and the cross-sectional area decrease from the upper end toward the lower end. In addition, the diameter and cross-sectional area of the pillar PL are larger than those of the lower end of the portion PLa penetrating from the stacked body LMa to the intermediate source line BSL at least on an upper surface of the lower end PLe. As an example, the diameter and cross-sectional area of the lower end PLe may be generally larger than the diameter and cross-sectional area of the portions PLa and PLb.

Thus, the pillar PL has a stepped portion at a height position of an interface between the intermediate source line BSL and the lower source line DSLa.

Each of the plurality of pillars PL includes a memory layer ME extending in the stacked body LM in the stacking direction, a channel layer CN penetrating the stacked body LM and connected to the intermediate source line BSL, a cap layer CP covering an upper surface of the channel layer CN, and a core layer CR serving as a core material of the pillar PL.

As illustrated in FIGS. 2B and 2C, the memory layer ME as a multilayer insulating layer has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except for the depth position of the intermediate source line BSL. In addition, the memory layer ME is also disposed on a bottom surface of the pillar PL reaching the depth of the lower source line DSLa.

The channel layer CN penetrates the stacked body LM, the upper source line DSLb, and the intermediate source line BSL inside the memory layer ME, and reaches the depth of the lower source line DSLa. More specifically, the channel layer CN extends along the outer shape such as the side surface and the bottom surface of the pillar PL via the memory layer ME. Note, however, that a part of the channel layer CN is in contact with the intermediate source line BSL on the side surface of the pillar PL, and is thereby electrically connected to the source line SL including the intermediate source line BSL.

Additionally, in the channel layer CN, the n-type impurity from the intermediate source line BSL is diffused in a predetermined range including a conduction portion with the intermediate source line BSL. The n-type impurity spreads in a predetermined range in the vertical direction of the channel layer CN starting from the conduction portion with the intermediate source line BSL. On the upper side of the channel layer CN, the impurities may reach, for example, the height position of at least the lowermost selection gate line SGS of one or more selection gate lines SGS of the stacked body LMa.

Further, the core layer CR is filled inside the channel layer CN. Note, however, that the lower end PLe of the pillar PL does not necessarily have to be completely filled with the core layer CR, and a gap may be included in the lower end PLe. Similarly, the portions PLa and PLb of the pillar PL does not necessarily have to be completely filled with the core layer CR, and a gap may be included in the vicinity of the central portion of the portions PLa and PLb.

The cap layer CP is arranged at the upper end of the pillar PL so as to cover at least the upper end of the channel layer CN, and is connected to the channel layer CN. In addition, the cap layer CP is connected to a bit line BL arranged in the insulating layer 53 via a plug CH arranged in the insulating layer OL as the uppermost layer of the stacked body LM and a plug VY arranged in the insulating layer 52. The bit line BL extends above the stacked body LM in a direction along the Y direction so as to intersect with a direction in which the word line WL is drawn out.

Note that in FIG. 2A, the plug VY is connected to only one pillar PL among the plurality of pillars PL belonging to the pattern of the selection gate line SGD partitioned by the separation layer SHE. The other pillars PL are connected to other bit lines BL extending in the direction along the Y direction in parallel with the bit line BL illustrated in FIG. 2A via plugs VY (not illustrated in FIG. 2A) at positions different from the cross section illustrated in FIG. 2A.

As illustrated in FIG. 2D and as described above, the plurality of pillars PL are arranged in a staggered manner, for example, when viewed from the stacking direction of the stacked body LM. Similarly to the pillars PL, the plugs CH connected to the plurality of pillars PL are also arranged in a staggered manner. Therefore, the center position of each plug CH substantially coincides with the center position of the pillar PL to be connected.

Furthermore, similarly to the pillars PL, the plugs VY connected to the plurality of pillars PL via the plugs CH are also arranged in a staggered manner. Note, however, that the center positions in the Y direction of the plugs VY arranged in the direction along the X direction are substantially arranged on a straight line indicated by a broken line in FIG. 2D. That is, the center positions of the plurality of plugs VY in the Y direction are offset from the center positions of the pillars PL in the Y direction every two columns.

More specifically, in two rows on the lower side of the drawing of the array of the plurality of plugs VY in the X direction, the center positions of the plurality of plugs VY in the Y direction are shifted to the lower side of the drawing from the center positions of the pillars PL in the Y direction. Additionally, the center positions of the plugs VY in the X direction are offset from the center positions of the pillars PL in the X direction.

Furthermore, in two rows on the upper side of the drawing of the array of the plurality of plugs VY in the X direction, the center positions of the plurality of plugs VY in the Y direction are shifted to the upper side of the drawing from the center positions of the pillars PL in the Y direction. Additionally, the center positions of the plugs VY in the X direction are offset from the center positions of the pillars PL in the X direction in a direction opposite to the above-described two rows of plugs VY on the lower side of the drawing.

With such an arrangement of the plugs VY, the pillars PL arranged in the section of the same selection gate line SGD separated by the separation layer SHE are connected to different bit lines BL via the plug VY. At this time, the bit line BL extends in the direction along the Y direction at a position overlapping with each plug VY in the X direction.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 2C, with the above configuration, a memory cell MC is formed in a portion facing each of the word lines WL on the side surface of the pillar PL. When a predetermined voltage is applied from the word line WL, data is written to and read from the memory cell MC.

As illustrated in FIG. 2B, with the above configuration, the selection gates STD and STS are formed in a portion facing the selection gate lines SGD and SGS. When predetermined voltages are applied from the selection gate lines SGD and SGS, the selection gates STD and STS are turned on or off, and the memory cell MC of the pillar PL to which the selection gates STD and STS belong can be brought into a selected state or a non-selected state.

In addition, for example, among one or more selection gate lines SGS of the stacked body LMa, the selection gate line SGS including at least the lowermost selection gate line SGS is used to apply an erase voltage for erasing data of the memory cell MC to the channel layer CN of the pillar PL. Since the above-described impurities reach at least the height position of the selection gate line SGS of the lowermost layer, the data erasure characteristic can be improved.

### (Method of Manufacturing Semiconductor Memory Device)

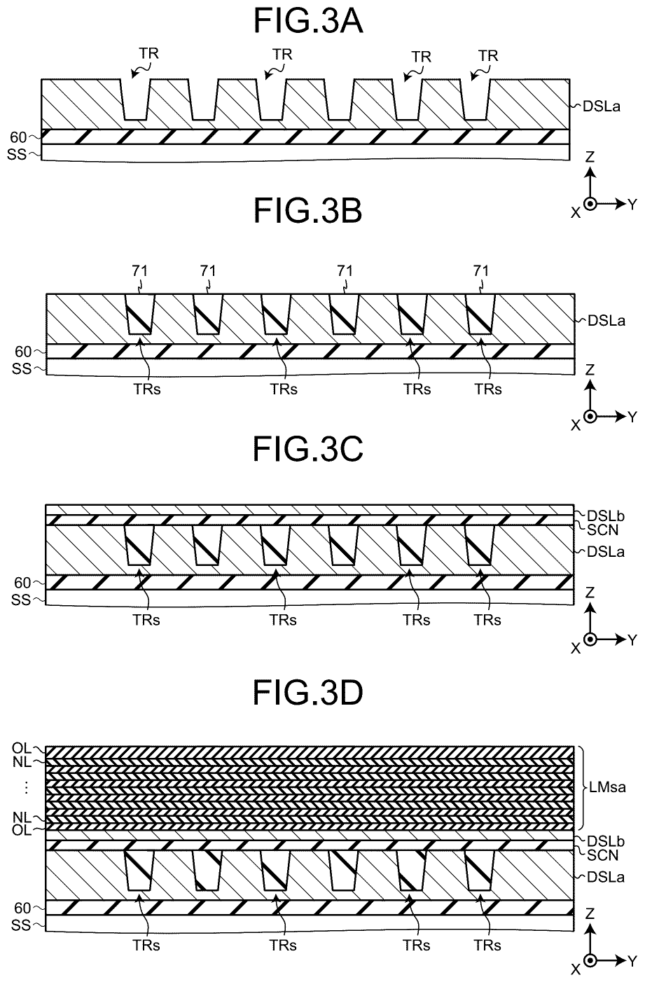

Next, a method of manufacturing the semiconductor memory device 1 of the embodiment will be described with reference to FIGS. 3A to 9C. FIGS. 3A to 9C are diagrams sequentially illustrating parts of the procedure of the method of manufacturing the semiconductor memory device 1 according to the embodiment. More specifically, FIGS. 3A to 9C are cross-sectional views along the Y direction of a region that later becomes the memory region MR, and illustrate a cross section of a portion corresponding to FIG. 2A described above.

As illustrated in FIG. 3A, a support substrate SS is prepared. As the support substrate SS, a semiconductor substrate such as a silicon substrate, an insulating substrate such as a ceramic substrate, a conductive substrate, or the like can be used.

In addition, the insulating layer 60 is formed on the upper surface side of the support substrate SS, and the lower source line DSLa is formed on the insulating layer 60. Further, a plurality of recesses TR are formed in the lower source line DSLa. The plurality of recesses TR are portions that later become the lower end PLe of the pillar PL.

Such a plurality of recesses TR can be formed by processing the lower source line DSLa by plasma etching or the like through a mask pattern (not illustrated) such as a photoresist layer. At this time, it is preferable to form a mask pattern by precise exposure using an ArF laser or the like so that the recess TR is formed in accordance with the fine pattern of the pillars PL.

As illustrated in FIG. 3B, a plurality of recesses TR formed in the lower source line DSLa are filled with a sacrificial layer 71 such as a carbon layer to form a plurality of lower structures TRs.

The carbon layer is a carbon-based layer formed by low pressure-chemical vapor deposition (LP-CVD) or the like. The sacrificial layer 71 such as a carbon layer may be formed by plasma CVD, spin coating, or the like.

As illustrated in FIG. 3C, an intermediate sacrificial layer SCN and the upper source line DSLb are formed in this order on the lower source line DSLa so as to cover the plurality of lower structures TRs. The intermediate sacrificial layer SCN as a first sacrificial layer is, for example, a silicon nitride layer or the like, and is a layer that is later replaced with a polysilicon layer or the like and becomes the intermediate source line BSL.

As illustrated in FIG. 3D, a stacked body LMsa in which a plurality of insulating layers NL and a plurality of insulating layers OL are alternately stacked one by one is formed on the upper source line DSLb. The insulating layer NL of the stacked body LMsa is, for example, a silicon nitride layer or the like, and functions as a second sacrificial layer that is later replaced with a conductive material and becomes the word line WL and the selection gate line SGS.

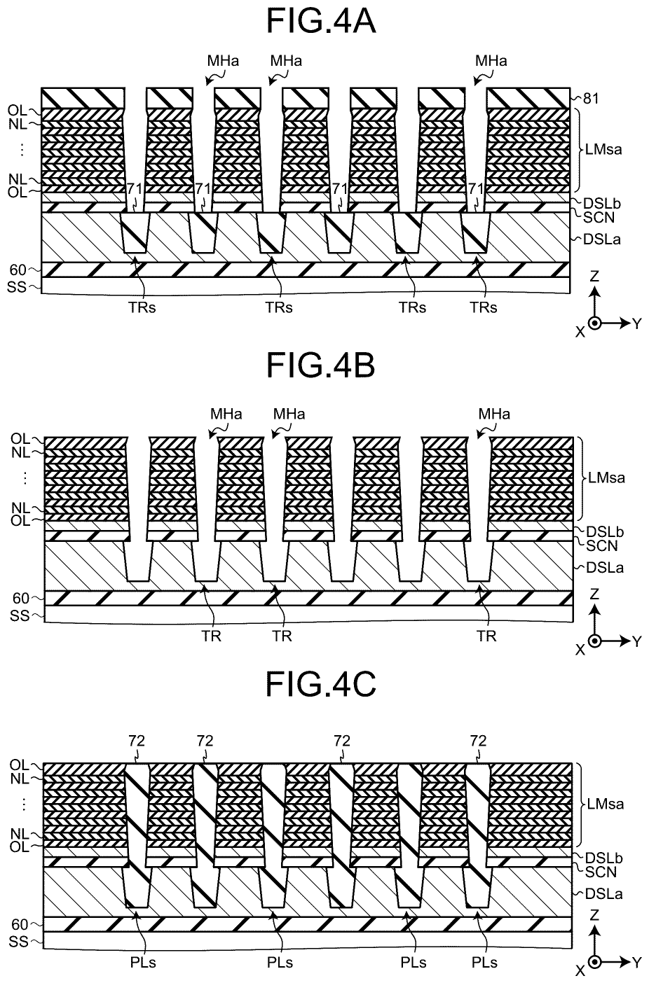

As illustrated in FIG. 4A, a plurality of memory holes MHa extending in the stacking direction of the stacked body LMsa and reaching the lower structure TRs are formed. The memory hole MHa later becomes the portion PLa of the pillar PL penetrating the stacked body LMa and the like.

Such memory holes MHa can be formed by processing the stacked body LMsa by, for example, plasma etching or the like through a mask pattern 81 such as a photoresist layer. At this time, it is preferable to form the mask pattern 81 by precise exposure using an ArF laser or the like so as to obtain a fine pattern of the pillars PL.

Additionally, at this time, by using a condition having selectivity with respect to the sacrificial layer 71 filled in the lower structure TRe, it is possible to stop the processing of the memory hole MHa at the upper surface position of the lower structure TRs using the sacrificial layer 71 as a stopper layer.

As illustrated in FIG. 4B, the mask pattern 81 is removed by ashing using oxygen plasma or other methods. At this time, the sacrificial layer 71 such as the carbon layer filled in the recess TR is also removed. As a result, the recess TR opens at the lower end of the memory hole MHa.

As illustrated in FIG. 4C, the memory hole MHa and the recess TR are filled with a sacrificial layer 72 such as a carbon layer. As a result, a pillar PLs in which the memory hole MHa and the recess TR are filled with the sacrificial layer 72 is formed.

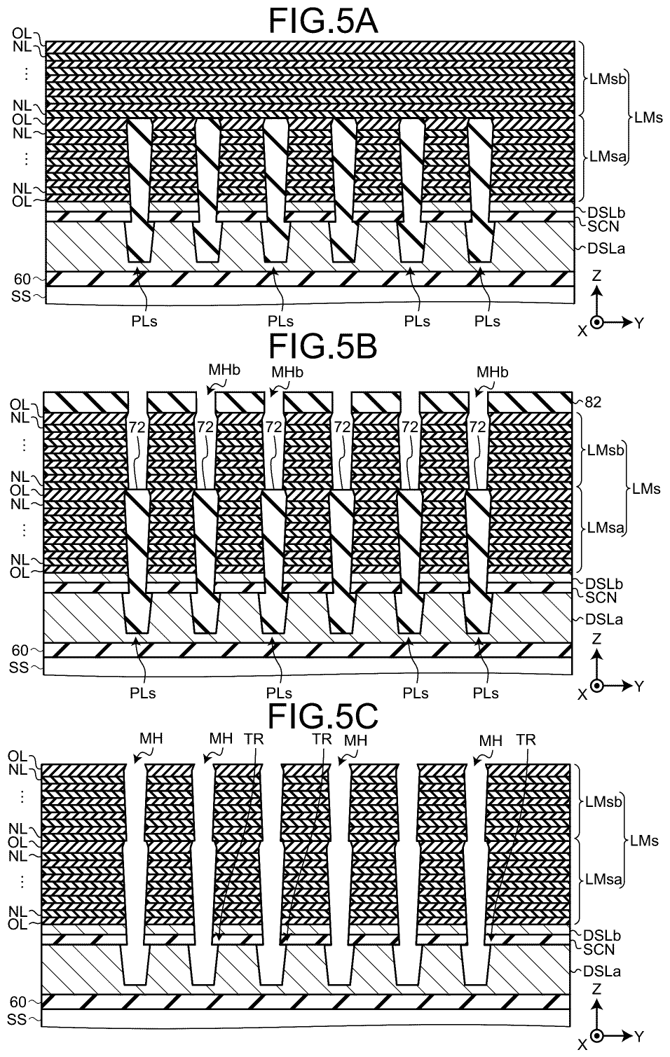

As illustrated in FIG. 5A, a stacked body LMsb which covers the plurality of pillars PLs and in which a plurality of insulating layers NL and a plurality of insulating layers OL are alternately stacked one by one is formed on the stacked body LMsa. The insulating layer NL of the stacked body LMsb functions as the second sacrificial layer that is later replaced with a conductive layer and becomes the word line WL and the selection gate line SGD.

As a result, a stacked body LMs including the stacked bodies LMsa and LMsb including the plurality of insulating layers NL is formed.

As illustrated in FIG. 5B, a plurality of memory holes MHb extending in the stacking direction of the stacked body LMsb are formed. The memory hole MHb later becomes the portion PLb of the pillar PL penetrating the stacked body LMb. The lower ends of the plurality of memory holes MHb reach the upper ends of the pillars PLs formed in the stacked body LMsa.

Such a memory hole MHb can also be formed by processing the stacked body LMsb by, for example, plasma etching or the like through a mask pattern 82 such as a photoresist layer. At this time, too, the processing of the memory hole MHb can be stopped at the upper end position of the pillar PLs using the sacrificial layer 72 filled in the pillar PLs as a stopper layer.

As illustrated in FIG. 5C, the mask pattern 82 is removed by ashing using oxygen plasma or other methods. At this time, the sacrificial layer 72 such as the carbon layer filled in the pillar PLs is also removed. As a result, the memory hole MHa and the recess TR are opened at the lower end of the memory hole MHb, and a memory hole MH penetrating the stacked body LMs, the upper source line DSLb, and the intermediate sacrificial layer SCN and connected at the lower end to the recess TR in the lower source line DSLa is formed.

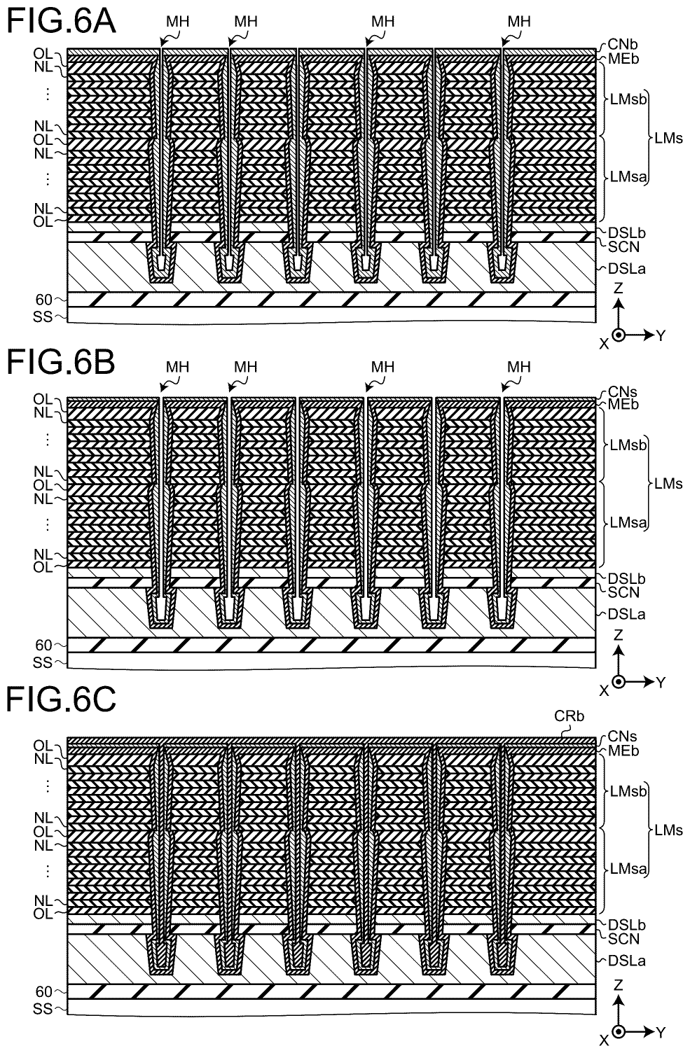

As illustrated in FIG. 6A, an insulating layer MEb and a semiconductor layer CNb are formed in this order in the memory hole MH and the recess TR. The insulating layer MEb is an insulating layer having a multilayer structure that later becomes the memory layer ME. The semiconductor layer CNb is a layer that later becomes the channel layer CN.

At this time, the semiconductor layer CNb is formed to be thicker than the finally obtained channel layer CN. Note, however, that the memory hole MH and the recess TR are not to be completely filled with the insulating layer MEb and the semiconductor layer CNb.

As a result, the side surface of the memory hole MH and the bottom surface of the memory hole MH where the lower source line DSLa is exposed are covered with the insulating layer MEb, and further covered with the semiconductor layer CNb via the insulating layer MEb. The insulating layer MEb and the semiconductor layer CNb are also formed in this order on an upper surface of the stacked body LMsb.

As illustrated in FIG. 6B, the inner wall of the channel layer CNb exposed to the gap in the memory hole MH is removed by etching to be thinned. As a result, a channel layer CNs having a desired layer thickness is formed in the memory hole MH.

As illustrated in FIG. 6C, the gap at the central portion of the memory hole MH and the recess TR is filled with an insulating layer CRb. The insulating layer CRb is a silicon oxide layer or the like that later becomes the core layer CR. The insulating layer CRb is also formed on the upper surface of the stacked body LMsb.

Note that the memory hole MH and the recess TR do not necessarily have to be completely filled with the insulating layer CRb.

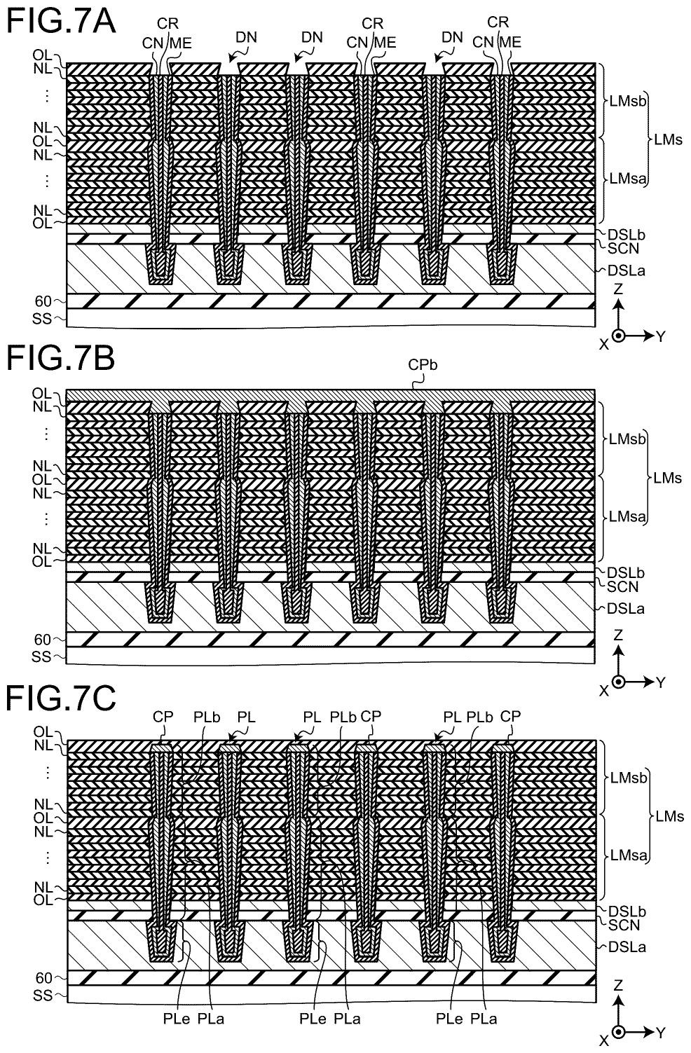

As illustrated in FIG. 7A, the insulating layer CRb, the semiconductor layer CNs, and the insulating layer MEb are sequentially etched back to be removed from the upper surface of the stacked body LMsb, and a depression DN is formed at the upper end of the memory hole MH. As a result, the insulating layer MEb and the semiconductor layer CNb are separated for each memory hole MH, and the memory layer ME and the channel layer CN are formed. In addition, the core layer CR is formed in the central portions of the memory layer ME and the channel layer CN. Note that the semiconductor layer CNs may be already removed from the upper surface of the stacked body LMsb at the time of the above-described thinning of FIG. 6B.

As illustrated in FIGS. 7B and 7C, a semiconductor layer is formed in the depression DN at the upper end of the memory hole MH, and the semiconductor layer also formed on the upper surface of the stacked body LMsb at that time is removed by etch-back or the like to form the cap layer CP at the upper end of the memory hole MH.

Further, after the cap layer CP is formed, the insulating layer OL is stacked thereon. As a result, the pillar PL in which the cap layer CP is buried in the uppermost insulating layer OL is formed.

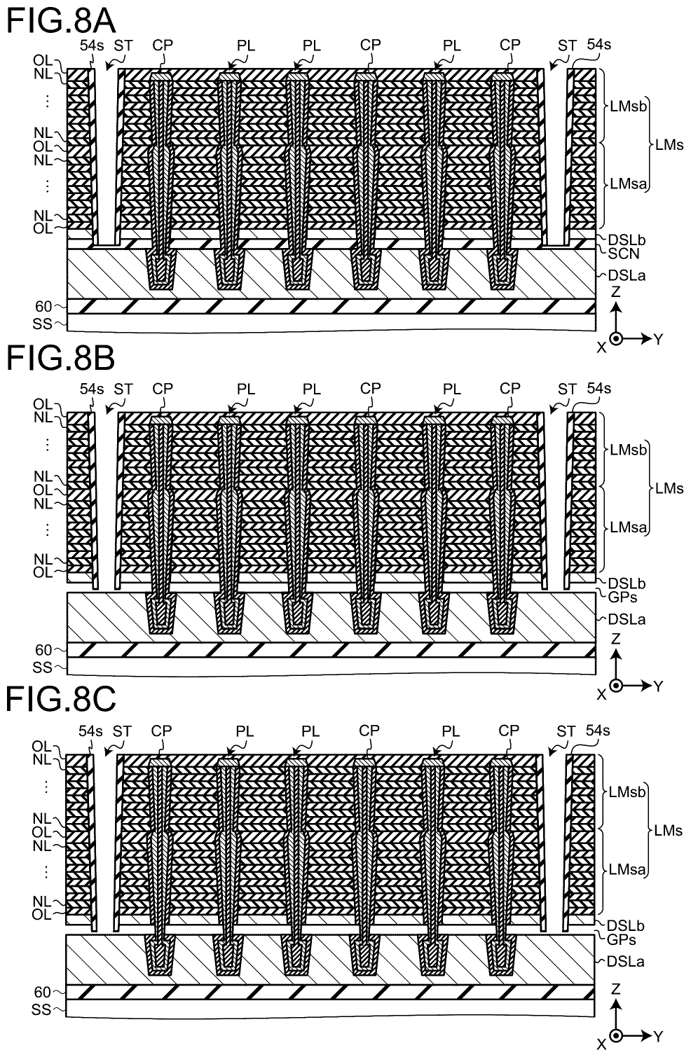

As illustrated in FIG. 8A, a slit ST that penetrates the stacked bodies LMsb and LMsa and the upper source line DSLb and reaches the intermediate sacrificial layer SCN is formed while avoiding interference with the plurality of memory holes MH. The slit ST also extends in the direction along the X direction in the stacked body LMs. A protective layer 54s is formed on side walls of the slit ST facing each other in the Y direction.

As illustrated in FIG. 8B, a removing liquid of the intermediate sacrificial layer SCN such as thermal phosphoric acid is caused to flow through the slit ST whose side wall is protected by the protective layer 54s, and the intermediate sacrificial layer SCN sandwiched between the lower source line DSLa and the upper source line DSLb is removed. At this time, since the side wall of the slit ST is protected by the protective layer 54s, the insulating layer NL in the stacked body LMs is prevented from also being removed.

As a result, a gap layer GPs is formed between the lower source line DSLa and the upper source line DSLb. In addition, a part of the memory layer ME formed in the memory hole MH is exposed in the gap layer GPs.

As illustrated in FIG. 8C, a chemical liquid or the like is caused to appropriately flow into the gap layer GPs through the slit ST, and the block insulating layer BK, the charge storage layer CT, and the tunnel insulating layer TN (see FIGS. 2B and 2C) of the memory layer ME exposed in the gap layer GPs are sequentially removed. As a result, the memory layer ME is removed from a part of the sidewall of the memory hole MH, and a part of the inner channel layer CN is exposed in the gap layer GPs.

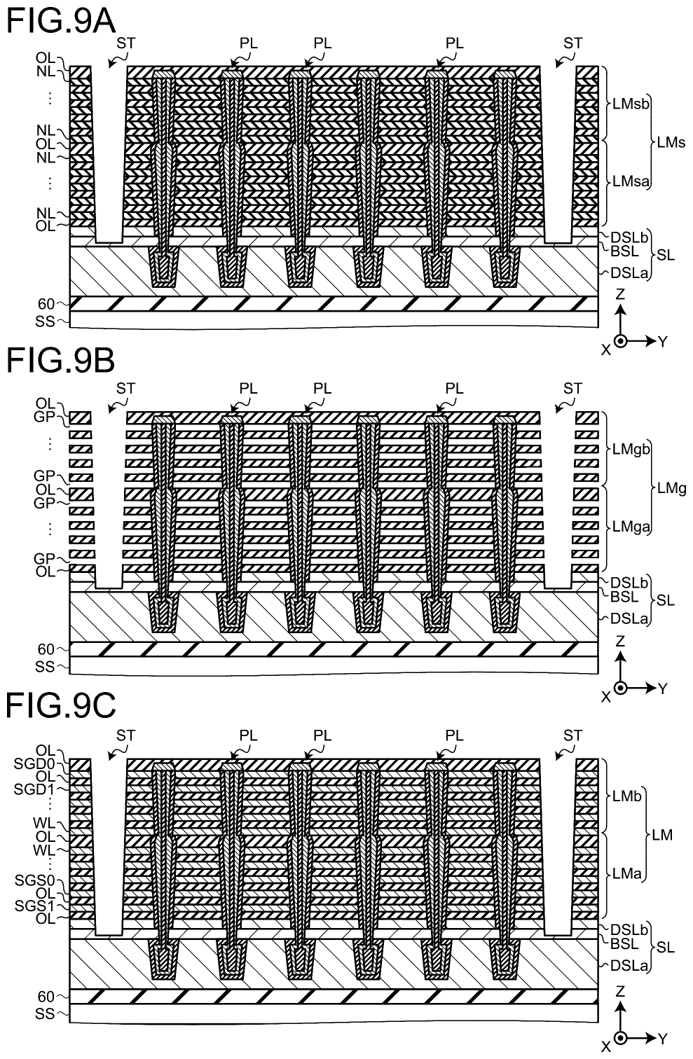

As illustrated in FIG. 9A, for example, a source gas such as amorphous silicon is injected from the slit ST, and the gap layer GPs is filled with amorphous silicon or the like.

At this time, for example, an n-type impurity such as phosphorus is added to the source gas, and the impurity is contained in the amorphous silicon. The impurity also diffuses into the channel layer CN through the portion exposed in the gap layer GPs. As a result, the impurity is also contained in a predetermined range of the channel layer CN starting from the height position of the gap layer GPs.

After the gap layer GPs is filled, the support substrate SS is subjected to a heat treatment to polycrystallize the amorphous silicon filled in the gap layer GPs, thereby forming the intermediate source line BSL containing polysilicon or the like. As a result, the source line SL in which the intermediate source line BSL is interposed between the upper source line DSLb and the lower source line DSLa is formed. Also, as a result, the channel layer CN in the memory hole MH is substantially single-crystallized, and a part of the channel layer CN is connected to the source line SL at the side surface via the intermediate source line BSL.

After the impurity is diffused into the channel layer CN and the channel layer CN is substantially single-crystallized, the protective layer 54s on the side wall of the slit ST is removed together with amorphous silicon and the like deposited in the slit ST at the time of forming the intermediate source line BSL.

As illustrated in FIG. 9B, a removing liquid of the insulating layer NL such as, for example, thermal phosphoric acid is caused to flow from the slit ST into the stacked body LMs to remove the insulating layer NL of the stacked body LMs. As a result, a stacked body LMg having a plurality of gap layers GP from which the insulating layers NL between the insulating layers OL are removed is formed. The stacked body LMg includes stacked bodies LMga and LMgb formed from the stacked bodies LMsa and LMsb, respectively.

As illustrated in FIG. 9C, a source gas of a conductive material such as tungsten or molybdenum is injected from the slit ST into the stacked body LMg, and the gap layer GP of the stacked body LMg is filled with the conductive material to form the plurality of word lines WL and the selection gate lines SGD and SGS. As a result, the stacked body LM including the stacked bodies LMa and LMb in which the plurality of word lines WL and the like and the plurality of insulating layers OL are alternately stacked one by one is formed.

As described above, the processing of forming the intermediate source line BSL from the intermediate sacrificial layer SCN and the processing of forming the word line WL from the insulating layer NL are also referred to as replacement processing.

Thereafter, the insulating layer 54 is formed on the side wall of the slit ST, and the insulating layer 54 is filled with the conductive layer 24 to form the plate contact LI. Note, however, that the insulating layer 54 or the like may be filled in the slit ST without forming the conductive layer 24 to form the plate-like member. Further, a plurality of separation layers SHE penetrating the selection gate line SGD and extending in the direction along the X direction in the stacked body LM are formed.

In addition, a plug CH that penetrates the uppermost insulating layer OL of the stacked body LM and is connected to the pillar is formed. In addition, the insulating layer 52 covering the upper surface of the stacked body LM is formed, and the plug VY that penetrates the insulating layer 52 and is connected to the plug CH is formed. Furthermore, the insulating layer 53 is formed on the insulating layer 52, and the bit line BL or the like connected to the plug VY is formed. In addition, an electrode pad or the like for electrically conducting with the peripheral circuit CBA is formed on an upper surface of the insulating layer 53.

In addition, the peripheral circuit CBA is formed on the semiconductor substrate SB separate from the support substrate SS on which the stacked body LM is formed, and the peripheral circuit CBA is covered with the insulating layer 40. In the insulating layer 40, a contact, a via, a wiring, or the like that draws the peripheral circuit CBA to the surface of the insulating layer 40 is formed and connected to an electrode pad or the like formed on an upper surface of the insulating layer 40.

Subsequently, the support substrate SS and the semiconductor substrate SB are bonded to each other by the insulating layers 50 and 40, respectively, and the electrode pads in the insulating layers 50 and 40 are connected. Thereafter, the support substrate SS is removed to expose the source line SL, and the electrode film EL is connected via the insulating layer 60 on which the plug PG is formed.

The semiconductor memory device 1 according to the embodiment is manufactured in the above-described manner.

### Comparative Example

A semiconductor memory device such as a three-dimensional nonvolatile memory has a pillar that penetrates a stacked body, extends into a source line, and is connected to an intermediate source line in the source line at a side surface. Such a pillar is formed, for example, by penetrating a stacked body including a sacrificial layer before replacement.

At this time, for example, it is preferable that a memory hole penetrating the stacked body is formed using the source line as a stopper layer, and then the memory hole is formed so as to reach a predetermined depth of the source line. Accordingly, the depths that the plurality of memory holes reach can be made uniform. However, in the memory hole formation process, in some cases, sufficient selectivity with the source line cannot be obtained.

In a semiconductor memory device of a comparative example, after the source line is formed and before the stacked body is formed, a recess extending in the source line is formed in advance, and after the stacked body is formed, a memory hole penetrating the stacked body and reaching the recess formed in the source line is formed. A method of manufacturing the semiconductor memory device of the comparative example will be described below.

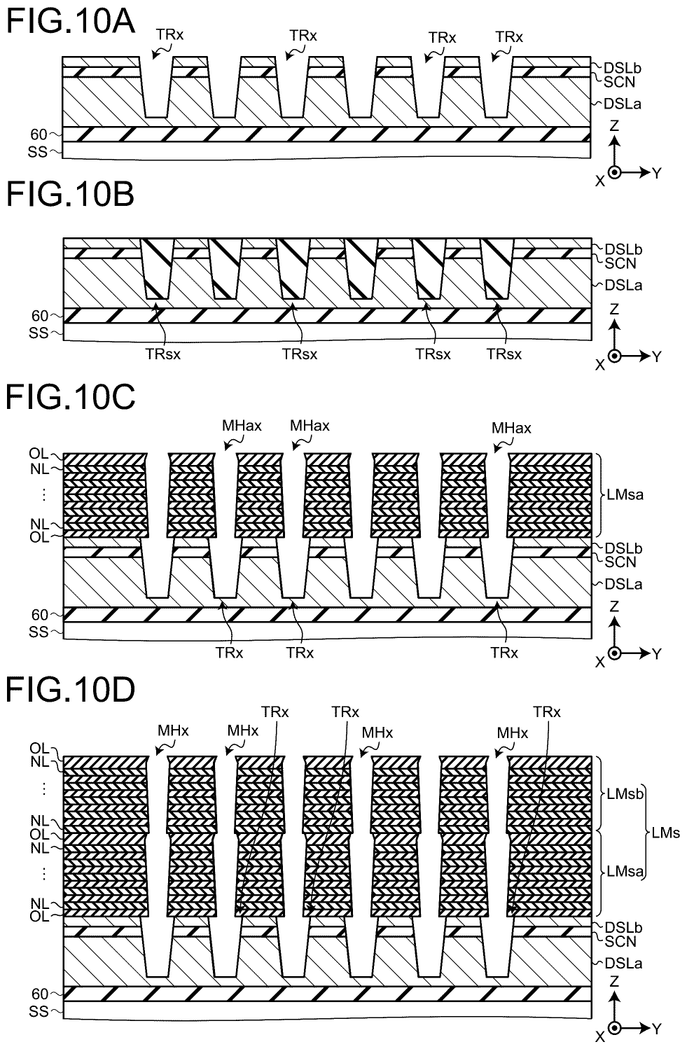

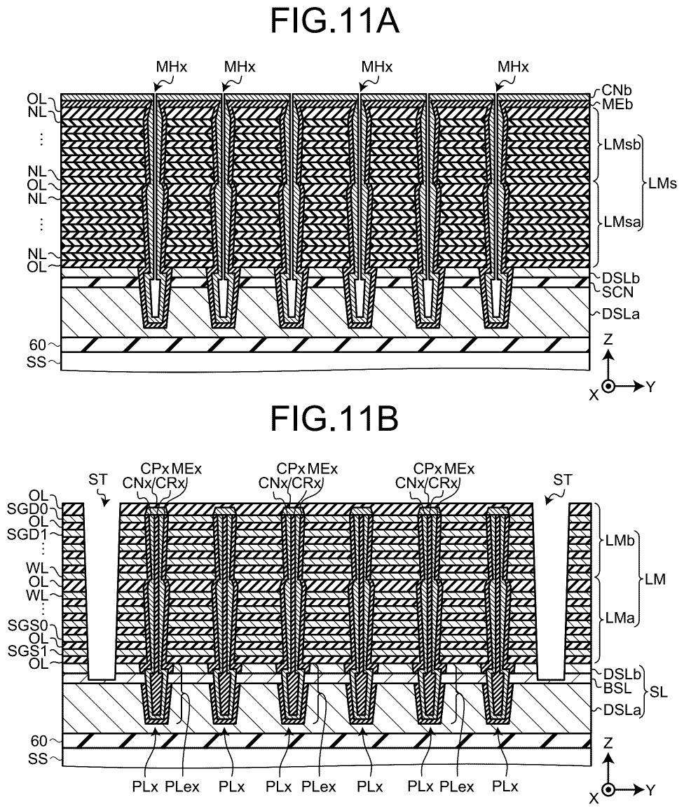

FIGS. 10A to 11B are cross-sectional views along the Y direction sequentially illustrating parts of the procedure of the method of manufacturing the semiconductor memory device according to the comparative example. As illustrated in FIG. 10A, in the semiconductor memory device of the comparative example, a lower source line DSLa, an intermediate sacrificial layer SCN, and an upper source line DSLb are formed, and a plurality of recesses TRx penetrating the upper source line DSLb and the intermediate sacrificial layer SCN and reaching a predetermined depth of the lower source line DSLa are formed. The subsequent processing is substantially similar to the method of manufacturing the semiconductor memory device 1 of the above-described embodiment.

That is, as illustrated in FIG. 10B, the plurality of recesses TRx are filled with a sacrificial layer such as a carbon layer to form a lower structure TRsx, and as illustrated in FIG. 10C, the sacrificial layer of the lower structure TRsx is used as a stopper layer to form a memory hole MHax that penetrates a stacked body LMsa on the upper source line DSLb and reaches the lower structure TRsx. The sacrificial layer of the lower structure TRsx is then removed. As illustrated in FIG. 10D, a stacked body LMsb is further formed, and a plurality of memory holes MHx penetrating the stacked bodies LMsb and LMsa and connected to the recesses TRx at the lower end are formed.

As illustrated in FIG. 11A, an insulating layer MEb and a semiconductor layer CNb covering the side wall and the bottom surface of the memory hole MHx and the recess TRx are formed in this order. Thereafter, the semiconductor layer CNb is slimmed to be filled with a core layer CRb. As illustrated in FIG. 11B, the core layer CRb, the semiconductor layer CNb, and the insulating layer MEb on the upper surface of a stacked body LMs are sequentially removed, a pillar PLx is formed by forming a cap layer CPx, for example, an intermediate sacrificial layer SCN is removed through the slit ST, and a memory layer MEx in a gap layer GPs is removed.

Thereafter, an intermediate source line BSL is formed through the slit ST, and the stacked body LMs is replaced through the slit ST to form a stacked body LM including a plurality of word lines WL and the like. Thus, the pillar PLx having a lower end PLex in a source line SL portion is formed.

As described above, in a case where the lower end PLex arranged in the source line SL portion and the portion penetrating the stacked body LM are formed separately, positional deviation may occur between the lower end PLex and the portion penetrating the stacked body LM. Examples of such positional deviation in the pillar PLx of the comparative example and in the pillar PL of the embodiment will be described below.

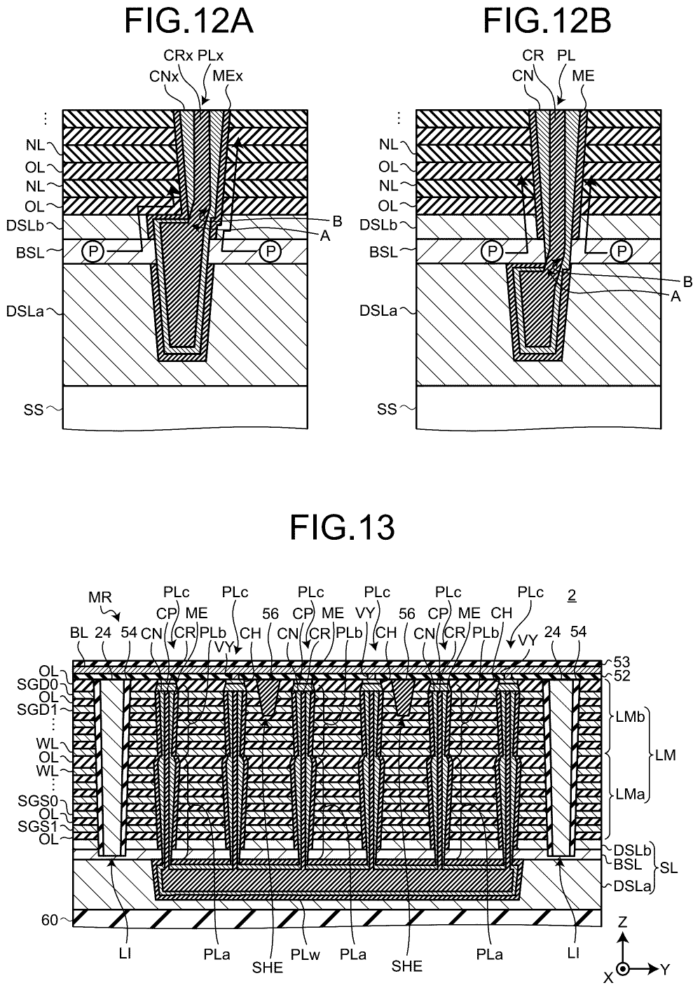

FIGS. 12A and 12B are schematic diagrams illustrating examples of the pillars PL and PLx in which the positional deviation occurs in the memory hole MH and MHx portions of the semiconductor memory devices according to the embodiment and the comparative example. More specifically, FIG. 12A is an enlarged cross-sectional view of the lower structure of the pillar PLx including the memory hole MHx portion and the recess TRx portion of the comparative example. FIG. 12B is an enlarged cross-sectional view of the lower structure of the pillar PL including the memory hole MH portion and the recess TR portion of the embodiment.

In the examples of FIGS. 12A and 12B, it is assumed that both the memory holes MH and MHx are formed to be shifted in the right direction in the drawing with respect to the recesses TR and TRx of the embodiment and the comparative example. That is, in the examples of FIGS. 12A and 12B, when viewed from the stacking direction of the stacked body LMs, the center points of the cross sections of the memory holes MH and MHx and the center points of the cross sections of the recesses TR and TRx do not coincide with each other.

As illustrated in FIG. 12A, when the memory layer MEx and a channel layer CNx are sequentially formed in the memory hole MHx and the recess TRx of the comparative example as described above, the channel layer CNx may be formed non-uniformly at the boundary portion between the memory hole MHx and the recess TRx.

More specifically, at the boundary portion between the memory hole MHx and the recess TRx, the corner formed by the side wall of the memory hole MHx and an upper surface of the recess TRx protrudes into the memory hole MHx in the shift direction of the recess TRx with respect to the memory hole MHx, that is, on the left side of the drawing. For this reason, the channel layer CNx may be formed to be thinner than other parts at point A on the left side of the drawing in the boundary portion. The processing of thinning the channel layer CNx further reduces the layer thickness of the channel layer CNx at point A. In some cases, the channel layer CNx is completely disconnected at point A.

In addition, at the boundary portion between the memory hole MHx and the recess TRx, a step is generated by the side wall of the memory hole MHx and the upper surface of the recess TRx on the opposite side in the shift direction of the recess TRx with respect to the memory hole MHx, that is, on the right side of the drawing. For this reason, the channel layer CNx may be formed to be thicker than other parts at point B on the right side of the drawing at the boundary portion due to, for example, retention of the source gas of the channel layer CNx in such a stepped portion.

In the configuration of the comparative example, the boundary portion between the memory hole MHx and the recess TRx is located above the conduction portion between the channel layer CNx and the intermediate source line BSL. Therefore, the portion including points A and B is in the path of the cell current flowing through the channel layer CNx, and may affect the electrical characteristics of the channel layer CNx.

Moreover, in the pillar PLx of the comparative example, when an impurity P is diffused into the channel layer CNx at the time of forming the intermediate source line BSL, there is a concern that the arrival height of the impurity P may be different in the channel layer CNx. This is because the length of the diffusion path of the impurity P from the intermediate source line BSL serving as the diffusion source to the stacked body LMx is different between the left side of the drawing and the right side of the drawing.

That is, the path from the intermediate source line BSL to the lower end of the stacked body LMs is longer on the left side of the drawing, which is the shift direction of the recess TRx, than on the right side of the drawing, which is the opposite side in the shift direction. Therefore, in the example of FIG. 12A, in the channel layer CNx on the left side of the drawing, the impurity P reaches only the height position of the lowermost insulating layer NL, for example. On the other hand, in the channel layer CNx on the right side of the drawing, the impurity P reaches a height equal to or higher than the height of the second insulating layer NL from the lowermost layer, for example.

The one or more insulating layers NL including the lowermost layer of the stacked body LMs later function as the selection gate line SGS. As described above, some of these selection gate lines SGS contribute to the data erasure of the memory cell, and the impurity P in the channel layer CNx has a role of improving this data erasure characteristic. Therefore, when the arrival height of the impurity P in the channel layer CNx is different, the erasure performance by the selection gate line SGS may be affected.

As illustrated in FIG. 12B, in the configuration of the embodiment, too, when the positional deviation occurs between the memory hole MH portion and the recess TR portion of the pillar PL, similarly to the comparative example, the layer thickness of the channel layer CN may vary at the boundary portion between the memory hole MH and the recess TR. That is, at point A in the shift direction of the recess TR, the channel layer CN becomes thinner than other parts or is disconnected, and at point B on the opposite side in the shift direction of the recess TR, the channel layer CN becomes thicker than other parts.

However, in the configuration of the embodiment, the boundary portion between the memory hole MH and the recess TR is located below the conduction portion between the channel layer CNx and the intermediate source line BSL. Therefore, the portion including points A and B is out of the path of the cell current flowing through the channel layer CN, and the influence on the electrical characteristics of the channel layer CN can be curbed.

Furthermore, in the configuration of the embodiment, when the impurity P is diffused into the channel layer CN at the time of forming the intermediate source line BSL, it is easy to align the arrival height of the impurity P in the channel layer CN. This is because the length of the diffusion path of the impurity P from the intermediate source line BSL serving as the diffusion source to the lower end of the stacked body LMs is substantially equal between the left side of the drawing and the right side of the drawing regardless of the presence or absence of the positional deviation between the memory hole MH and the recess TR.

Therefore, the impurity P can reach the height position of the same insulating layer NL among the plurality of insulating layers NL in the stacked body LMs in the channel layer CN on both the left side of the drawing and the right side of the drawing. In the example of FIG. 12B, the impurity P reaches, for example, the height position of the lowermost insulating layer NL of the stacked body LMs, and the arrival height is substantially equal in the left-right direction of the drawing. Thus, the variation in the erase performance of selection gate line SGS can be curbed.

According to the semiconductor memory device 1 of the embodiment, the pillar PL has a shape in which the cross-sectional area when viewed from the stacking direction of the stacked body LM is larger at the height position of the lower source line DSLa than at the height position of the intermediate source line BSL, and has the stepped portion at the height position of the interface between the lower source line DSLa and the intermediate source line BSL.

As described above, the connection portion between the memory hole MH and the recess TR is arranged at the height position of the interface between the lower source line DSLa and the intermediate source line BSL, and the stepped portion is arranged at the height position of the interface, so that the influence of the positional deviation between the portions PLa and PLb penetrating the stacked body LM of the pillars PL and the lower end PLe in the lower source line DSLa can be curbed.

According to the semiconductor memory device 1 of the embodiment, when viewed from the stacking direction of the stacked body LM, the center point of the pillar PL at the height position of the lower source line DSLa is shifted in a predetermined direction along the cross section of the pillar PL with respect to the center point of the pillar PL at the height position of the intermediate source line BSL, and the channel layer CN in the stepped portion of the pillar PL is thicker in a direction opposite to the predetermined direction than that in the predetermined direction.

As described above, even in a case where the channel layer CN in the stepped portion is thicker than other parts, the stepped portion is at a position deviated from the cell current path of the channel layer CN as described above, and thus, it is possible to curb the influence on the electrical characteristics of the channel layer CN.

According to the semiconductor memory device 1 of the embodiment, the channel layer CN discontinuously extends from the intermediate source line BSL to the lower source line DSLa in the predetermined direction. As described above, even in a case where the channel layer CN is disconnected at the stepped portion, the stepped portion is located at a position deviated from the cell current path of the channel layer CN as described above, and thus, it is possible to curb the influence on the electrical characteristics of the channel layer CN.

According to the semiconductor memory device 1 of the embodiment, the impurity in the channel layer CN reaches the height position of the same selection gate line SGS among the one or more selection gate lines SGS on the predetermined direction side and on the opposite side of the predetermined direction of the channel layer CN.

As described above, even when there is a positional deviation between the portions PLa and PLb penetrating the stacked body LM and the lower end PLe in the lower source line DSLa of the pillar PL, the arrival height of the impurity diffused into the channel layer CN in the stacked body LM can be made substantially uniform. Accordingly, the data erasure characteristic of the memory cell MC can be improved.

### (Modification)

Next, a semiconductor memory device 2 according to a modification of the embodiment will be described with reference to FIGS. 13 to 15C. The semiconductor memory device 2 of the modification is different from the above-described embodiment in that a plurality of pillars PLc are connected at the height position of a lower source line DSLa.

In the following drawings, the same reference numerals are given to the same configurations as those of the embodiment, and the description thereof may be omitted.

FIG. 13 is a cross-sectional view along the Y direction illustrating an example of a configuration of the semiconductor memory device 2 according to the modification of the embodiment. In FIG. 13, structures below an insulating layer 60 and above an insulating layer 53 to be described later are omitted.

As illustrated in FIG. 13, each of the plurality of pillars PLc includes a portion PLa penetrating a stacked body LMa, an upper source line DSLb, and an intermediate source line BSL, and a portion PLb penetrating a stacked body LMb, and is connected to a common lower end PLw arranged in the lower source line DSLa at the lower end of the portion PLa.

Memory layers MR and channel layers CN of the pillars PLc extend along the outer shape of the portions PLa and PLb of the pillars PLc, are connected to each other at an upper surface of the lower end PLw common to the pillars PLc, and cover the side surface and the bottom surface of the lower end PLw.

Core layers CR of the pillars PLc fill the inside of the channel layers CN of the portions PLa and PLb of the pillars PLc and the inside of the channel layer CN of the lower end PLw common to the pillars PLc. Note, however, that the lower end PLw does not necessarily have to be completely filled with the core layer CR and may have a gap, and the same applies to the portions PLa and PLb.

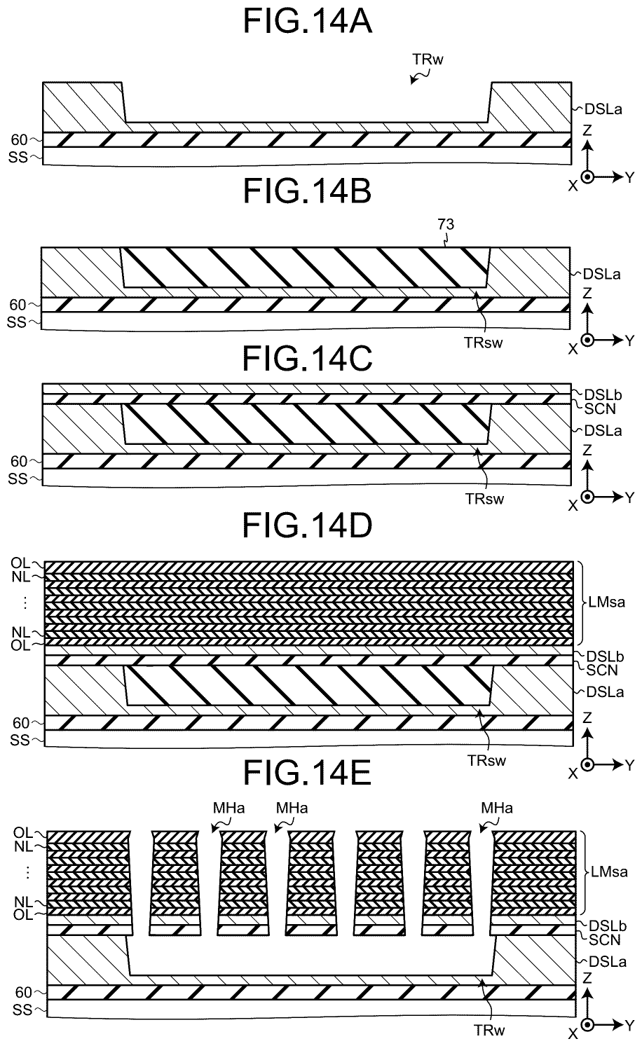

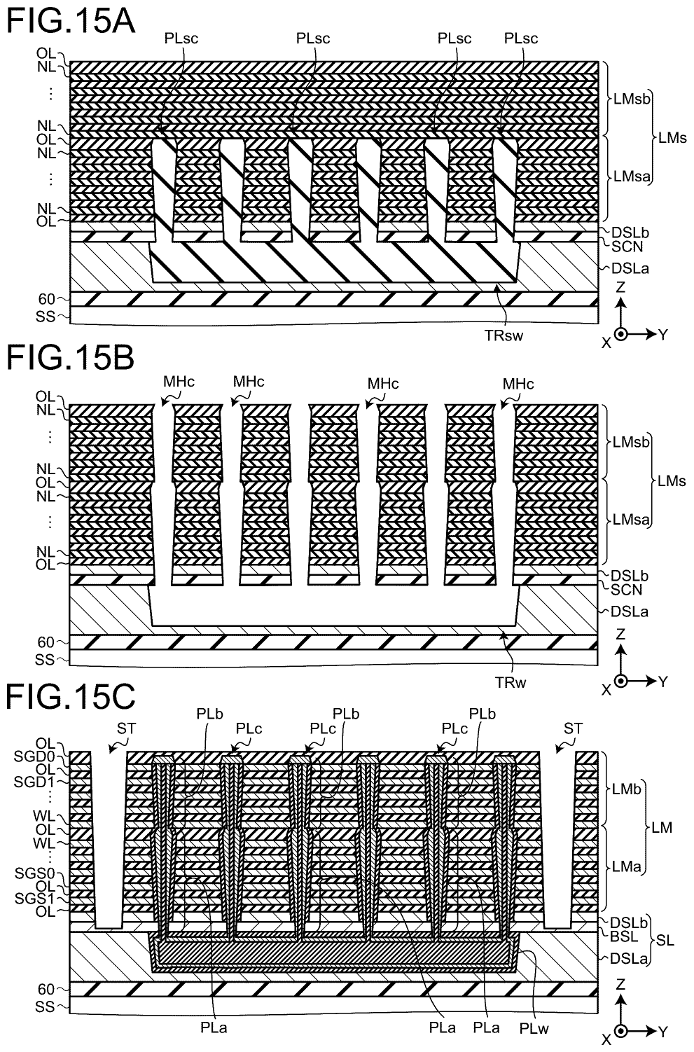

FIGS. 14A to 15C are cross-sectional views along the Y direction sequentially illustrating parts of the procedure of the method of manufacturing the semiconductor memory device 2 according to the modification of the embodiment.

As illustrated in FIG. 14A, the insulating layer 60 and the lower source line DSLa are formed in this order on a support substrate SS. In addition, a recess TRw is formed in the lower source line DSLa. The recess TRw is a portion that later becomes the lower end PLw of the pillar PLc.

Such a recess TRw can also be formed by processing the lower source line DSLa by plasma etching or the like through a mask pattern (not illustrated) such as a photoresist layer, for example, similarly to the recess TR of the above-described embodiment.

Note, however, that the recess TRw to be the lower end PLw common to the plurality of pillars PL does not need to be formed in accordance with the fine pattern of the pillars PL. Therefore, a mask pattern can be formed by exposure using, for example, a KrF laser or the like.

Subsequent processing is similar to the method of manufacturing the semiconductor memory device 1 of the above-described embodiment.

That is, as illustrated in FIG. 14B, a lower structure TRsw is formed by filling the recess TRw with a sacrificial layer 73 such as a carbon layer, and as illustrated in FIG. 14C, the intermediate sacrificial layer SCN covering the lower structure TRsw and the upper source line DSLb are formed in this order on the lower source line DSLa.

Furthermore, as illustrated in FIG. 14D, a stacked body LMsa is formed above the upper source line DSLb, and as illustrated in FIG. 14E, a memory hole MHa penetrating the stacked body LMsa and reaching the lower structure TRsw is formed with the sacrificial layer 73 of the lower structure TRsw as a stopper layer. The sacrificial layer 73 of the lower structure TRsw is then removed.

In addition, as illustrated in FIG. 15A, a stacked body LMsb covering pillars PLsc filled with a sacrificial layer such as a carbon layer is formed above the stacked body LMsa, and as illustrated in FIG. 15B, a plurality of memory holes MHc penetrating the stacked bodies LMsb and LMsa and connected to the recess TRw at the lower end are formed.

Thereafter, a memory layer ME and a thick channel layer CNb (see FIG. 6A) are formed in the memory hole MHc to be thinned, and then the core layer CR is filled, and a cap layer CP is formed at the upper end (see FIG. 7C). In addition, the intermediate source line BSL is formed through the slit ST (see FIG. 8A), and the stacked body LMs is replaced to form a stacked body LM including a plurality of word lines WL and the like.

Consequently, as illustrated in FIG. 15C, the pillar PLc having the lower end PLw in a source line SL is formed.

Thereafter, a plate contact LI, plugs CH and VY, a bit line BL, and the like are further formed, a semiconductor substrate SB on which a peripheral circuit CBA is formed is bonded, and an electrode film EL is connected to the source line SL via the insulating layer 60 on which a plug PG is formed.

As described above, The semiconductor memory device 2 of the modification is manufactured in the above-described manner.

According to the semiconductor memory device 2 of the modification, the plurality of pillars PLc are connected to each other at the height position of the lower source line DSLa. Thus, the processing difficulty of the lower end PLw of the pillar PLc can be reduced, and, for example, a mask pattern for forming the lower end PLw can be formed by exposure using a KrF laser instead of an ArF laser or the like. Therefore, the manufacturing cost of the semiconductor memory device 2 can be reduced.

Note that in the above-described embodiment and modification, the stepped region SR is arranged at both ends in the X direction of the stacked body LM. However, for example, a stepped region including a stepped portion formed by digging down the central portion of the stacked body in a mortar shape may be disposed in the stacked body.

In addition, in the above-described embodiment and modification, the peripheral circuit CBA contributing to the operation of the memory cell MC is disposed on the semiconductor substrate SB bonded above the stacked body LM. However, the stacked body may be stacked above a peripheral circuit disposed on a semiconductor substrate including a transistor. Alternatively, the stacked body may be disposed on the same semiconductor substrate as the peripheral circuit.

In addition, in the above-described embodiment and modification, the semiconductor memory devices 1 and 2 include the two-tier stacked body LM including the stacked bodies LMa and LMb. However, the semiconductor memory device may include a stacked body of one tier or three tiers or more. Note that in the multi-tier type semiconductor memory device, it is easy to further increase the number of stacked word lines WL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first semiconductor layer;
a second semiconductor layer provided above the first semiconductor layer;
a third semiconductor layer interposed between the first and second semiconductor layers;
a stacked body provided above the second semiconductor layer, in which a plurality of conductive layers are stacked one by one while being separated from each other; and
a pillar including a channel layer that extends through the stacked body, the second semiconductor layer, and the third semiconductor layer in a stacking direction of the stacked body and reaches a predetermined depth of the first semiconductor layer, wherein
the channel layer is electrically connected to the third semiconductor layer on a side surface, and
the pillar has a cross-sectional area as viewed from the stacking direction that is larger at a height position of the first semiconductor layer than at a height position of the third semiconductor layer, and has a stepped portion at a height position of an interface between the first semiconductor layer and the third semiconductor layer.

2. The semiconductor memory device according to claim 1, wherein
the pillar is included in a plurality of pillars, and
the plurality of pillars are provided independently of each other.

3. The semiconductor memory device according to claim 1, wherein
the pillar is included in a plurality of pillars, and
the plurality of pillars are connected to each other at a height position of the first semiconductor layer.

4. The semiconductor memory device according to claim 1, wherein
a center point of a cross section of the pillar viewed from the stacking direction does not coincide between the height position of the first semiconductor layer and the height position of the third semiconductor layer.

5. The semiconductor memory device according to claim 4, wherein
the channel layer extends along an outer shape of the pillar, and has a layer thickness different from a layer thickness of other portions at the stepped portion.

6. The semiconductor memory device according to claim 4, wherein
the center point at the height position of the first semiconductor layer is shifted in a first direction along the cross section with respect to the center point at the height position of the third semiconductor layer, and
the channel layer at the stepped portion is thicker in a second direction opposite to the first direction than in the first direction.

7. The semiconductor memory device according to claim 6, wherein
the channel layer discontinuously extends from the third semiconductor layer to the first semiconductor layer in the first direction.

8. The semiconductor memory device according to claim 6, wherein
the third semiconductor layer contains an impurity of a first conductivity type.

9. The semiconductor memory device according to claim 8, wherein
the channel layer contains the impurity in a predetermined range including a conducting portion with the third semiconductor layer, and
the impurity in the channel layer reaches a height position of the same conductive layer among the plurality of conductive layers on the first direction side and on the second direction side of the channel layer.

10. A semiconductor memory device comprising:
a first semiconductor layer;
a second semiconductor layer provided above the first semiconductor layer;
a third semiconductor layer interposed between the first and second semiconductor layers;
a stacked body provided above the second semiconductor layer, in which a plurality of conductive layers are stacked one by one while being separated from each other; and
a plurality of pillars each including a channel layer that extends through the stacked body, the second semiconductor layer, and the third semiconductor layer in a stacking direction of the stacked body, wherein
each of the channel layers is electrically connected to the third semiconductor layer on a side surface, and
the plurality of pillars are connected to each other at a height position of the first semiconductor layer.

11. A method of manufacturing a semiconductor memory device, comprising:
forming a first semiconductor layer;
forming a recess in the first semiconductor layer;
forming a stopper layer in the recess;
forming a first sacrificial layer above the first semiconductor layer on which the stopper layer is formed;
forming a second semiconductor layer above the first sacrificial layer;
forming a stacked body in which a plurality of second sacrificial layers are stacked one by one while being separated from each other above the second semiconductor layer;
forming a memory hole that extends through the stacked body, the second semiconductor layer, and the first sacrificial layer in a stacking direction of the stacked body and reaches the stopper layer; and
forming a channel layer in the memory hole.

12. The method of manufacturing a semiconductor memory device according to claim 11, further comprising:
removing the stopper layer from the inside of the recess before forming the channel layer; and
when forming the channel layer, forming the channel layer so as to cover a side wall of the memory hole, a side wall of the recess, and a bottom surface of the recess.

13. The method of manufacturing a semiconductor memory device according to claim 12, further comprising:
removing the first sacrificial layer to expose the channel layer at a height position of the first sacrificial layer; and
forming a third semiconductor layer in a gap generated by removing the first sacrificial layer to electrically connect to the channel layer.

14. The method of manufacturing a semiconductor memory device according to claim 13, further comprising:
forming a multilayer insulating layer covering the side wall of the memory hole, the side wall of the recess, and the bottom surface of the recess before forming the channel layer;
after forming the channel layer via the multilayer insulating layer, removing the first sacrificial layer to expose the multilayer insulating layer at the height position of the first sacrificial layer; and
removing the multilayer insulating layer exposed at the height position of the first sacrificial layer to expose the channel layer.

15. The method of manufacturing a semiconductor memory device according to claim 13, further comprising
when forming the third semiconductor layer, including an impurity of a first conductivity type in the third semiconductor layer.

16. The method of manufacturing a semiconductor memory device according to claim 15, further comprising
when forming the third semiconductor layer, also including the impurity in the channel layer via the third semiconductor layer.

17. The method of manufacturing a semiconductor memory device according to claim 11, further comprising:
when forming the recess, forming a plurality of recesses in the first semiconductor layer; and
when forming the memory hole, forming a plurality of memory holes respectively reaching the plurality of recesses.

18. The method of manufacturing a semiconductor memory device according to claim 11, further comprising
when forming the memory hole, forming a plurality of memory holes reaching the stopper layer formed in the recess.

19. The method of manufacturing a semiconductor memory device according to claim 11, further comprising
when forming the memory hole, making a cross-sectional area of a lower end of the memory hole as viewed from the stacking direction smaller than a cross-sectional area of an upper surface of the recess.

20. The method of manufacturing a semiconductor memory device according to claim 19, further comprising
when forming the memory hole, allowing positional deviation within a predetermined range between a center point of a cross section of the memory hole and a center point of a cross section of the recess when viewed from the stacking direction.
